(19) United States
(12) Patent Application Publication
(10) Pub. No.: US 2022/0376464 A1
(43) Pub. Date: Nov. 24, 2022

(54) SEMICONDUCTOR OPTICAL INTEGRATED DEVICE AND MANUFACTURING METHOD THEREOF

(71) Applicant: Mitsubishi Electric Corporation, Tokyo (JP)

(72) Inventors: Kazuhisa TAKAGI, Tokyo (JP); Akitsugu NIWA, Tokyo (JP); Kenichi ABE, Tokyo (JP)

(73) Assignee: Mitsubishi Electric Corporation, Tokyo (JP)

(21) Appl. No.: 17/771,104

(22) PCT Filed: Jan. 16, 2020
(86) PCT No.: PCT/JP2020/001274

§ 371 Date: Apr. 22, 2022

(51) Int. Cl. H01S 5/026; H01S 5/10; G02B 6/122

(52) U.S. Cl. CPC H01S 5/0264; H01S 5/1014; G02B 6/1228

(57) ABSTRACT

Provided here are: a semiconductor laser section formed on a surface of a semiconductor substrate; a spot-size converter section in which an optical waveguide having a core layer for propagating laser light emitted from the semiconductor laser section is provided; and a monitor PD section which is provided on the spot-size converter section laterally with respect to a propagation direction of the laser light; wherein, the regions of a PD anode electrode and a PD cathode electrode in the monitor PD section are partially opposed to each other through an insulating film, so that the surge breakdown voltage of the monitor PD section is increased.

### TECHNICAL FIELD

The present application relates to a semiconductor optical integrated device and a manufacturing method thereof.

### BACKGROUND ART

Recently, because of the requirement for dealing with an increasing transmission capacity in fiber optic communications, the demand is expanding for, instead of a conventional configuration in which a semiconductor light source and a monitor PD (Photodiode) are formed into a module in a separated manner, a device that has a structure in which the function of the monitor PD is integrated in a light source device in order to achieve a high bit rate by an implementation of highly densified elements and optical members.

### CITATION LIST

### Patent Document

Patent Document 1: Japanese Patent Application Laid-open No. S63-222485 (Page 3, Upper-right Column, Line 14 to Lower-right Column, Line 13; FIG. 4)

### SUMMARY OF THE INVENTION

### Problems to be Solved by the Invention

According to Patent Document 1, the monitor PD section has a mesa type structure and thus, under application of a surge voltage thereon, the density of a current toward the absorption layer is higher than that of the planar type structure generally employed in the monitor PD as a single device, so that there is a problem that the surge breakdown voltage is as low as less than 100 V.

This application discloses a technique for solving the problem as described above, and an object thereof is to provide a semiconductor optical integrated device with an increased surge breakdown voltage of the monitor PD section, and a manufacturing method thereof.

### Means for Solving the Problems

A semiconductor optical integrated device disclosed in this application is characterized by comprising: a semiconductor laser section formed on a surface of a semiconductor substrate; a light propagation section in which an optical waveguide having a core layer for propagating laser light emitted from the semiconductor laser section is provided; and a monitor photodiode section which is provided on the light propagation section laterally with respect to a propagation direction of the laser light; wherein, a part of a region of one of electrodes in the monitor photodiode section is opposed, through an insulating film, to a part of a region of another one of the electrodes in the monitor photodiode section and/or a part of a region of a front-surface side electrode in the semiconductor laser section.

A manufacturing method of a semiconductor optical integrated device, disclosed in this application is characterized by comprising, a step of forming, using a light propagation section in which an optical waveguide having a core layer for propagating laser light emitted from a semiconductor laser section formed on a surface of a semiconductor substrate is provided, a monitor photodiode section on the light propagation section to be provided laterally with respect to a propagation direction of the laser light, wherein, in said step of forming the monitor photodiode section, the monitor photodiode section is formed so that a part of a region of one of electrodes in the monitor photodiode section is opposed, through an insulating film, to a part of a region of another one of the electrodes in the monitor photodiode section and/or a part of a region of a front-surface side electrode in the semiconductor laser section.

### Effect of the Invention

According to this application, because a capacitance is created between such double-layered electrodes that are opposed to each other through the insulating film, a part of electric charges from a human body will be stored partially in the capacitance and thus the voltage applied to the monitor PD will be reduced, so that the surge breakdown voltage of the monitor PD section is increased.

### BRIEF DESCRIPTION OF THE DRAWINGS

FIG. 1 is a sectional view showing a configuration about a semiconductor optical integrated device according to Embodiment 1.

FIG. 2 is a top view showing a configuration about the semiconductor optical integrated device according to Embodiment 1.

FIG. 3 is a sectional view showing a configuration about the semiconductor optical integrated device according to Embodiment 1.

FIG. 4 is a sectional view showing another configuration about a semiconductor optical integrated device according to Embodiment 1.

FIG. 5 is a set of sectional views showing another configuration about a semiconductor optical integrated device according to Embodiment 1.

FIG. 6 is a set of sectional views showing another configuration about a semiconductor optical integrated device according to Embodiment 1.

FIG. 7 is a set of top views for illustrating a manufacturing method about a semiconductor optical integrated device according to Embodiment 1.

FIG. 8 is a flowchart for illustrating steps in the manufacturing method about a semiconductor optical integrated device according to Embodiment 1.

FIG. 9 is a sectional view showing another configuration about a semiconductor optical integrated device according to Embodiment 1.

FIG. 10 is a set of top views for illustrating another manufacturing method about a semiconductor optical integrated device according to Embodiment 1.

FIG. 11 is a flowchart for illustrating steps in the other manufacturing method about a semiconductor optical integrated device according to Embodiment 1.

FIG. 12 is a top view showing a configuration about a semiconductor optical integrated device according to Embodiment 2.

FIG. 13 a top view showing another configuration about a semiconductor optical integrated device according to Embodiment 2.

FIG. 14 is a top view showing a configuration about a semiconductor optical integrated device according to Embodiment 3.

FIG. 15 a top view showing another configuration about a semiconductor optical integrated device according to Embodiment 3.

### MODES FOR CARRYING OUT THE INVENTION

### Embodiment 1

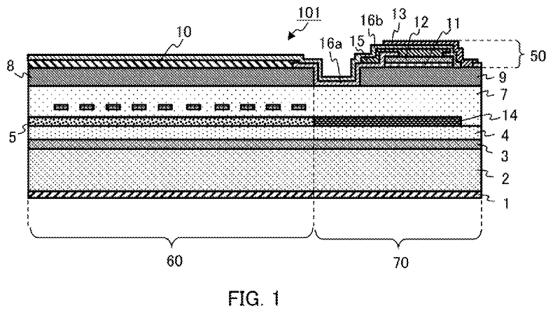

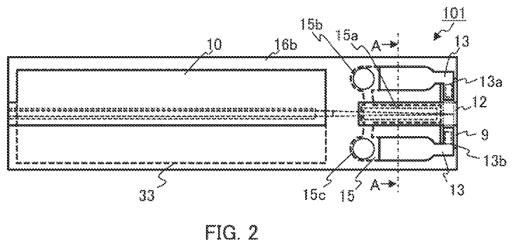

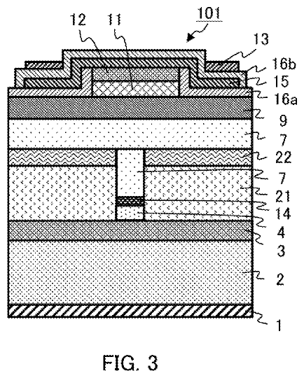

FIG. 1 is a sectional view in a resonator direction showing a configuration of a semiconductor optical integrated device according to Embodiment 1, and FIG. 2 is a top view thereof. FIG. 3 is a sectional view of the semiconductor optical integrated device at an A-A arrow position in FIG. 2.

As shown in FIG. 1 to FIG. 3, a semiconductor optical integrated device 101 according to Embodiment 1 is configured with: a semiconductor laser (LD, Laser diode) section 60; a spot-size converter section 70 as a light propagation section in which an optical waveguide, where no current is injected, having a core layer for propagating laser light emitted from the semi-conductor laser section is provided; and a monitor PD section 50 which is provided on the spot-size converter section laterally with respect to the propagation direction of the laser light. It is formed of a cathode electrode 1, an n-type indium phosphide substrate 2 having a thickness of about 100 μm, an n-InP buffer layer 3, an n-InP cladding layer 4, an active layer 5 in the semiconductor laser section 60, an Fe-doped InP current blocking layer 21, an n-InP current blocking layer 22, a p-type indium phosphide (hereinafter, abbreviated as “p-InP”) cladding layer 7, p-type InGaAs contact layers 8, 9, an LD anode electrode 10, an LD anode underlying electrode 33, an optical waveguide 14 made of i-InGaAsP in the spot-size converter section 70, an undoped indium phosphide (hereinafter, abbreviated as “i-InP”) electric-field relaxation layer 11 in the monitor PD section 50, an n-InGaAs contact layer 12, PD anode electrodes 13, a PD cathode electrode 15, insulating films 16a, 16b made of SiO₂, and so on.

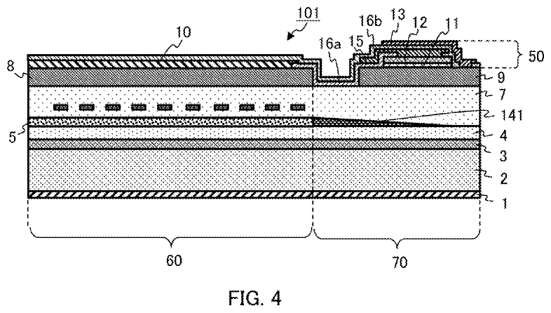

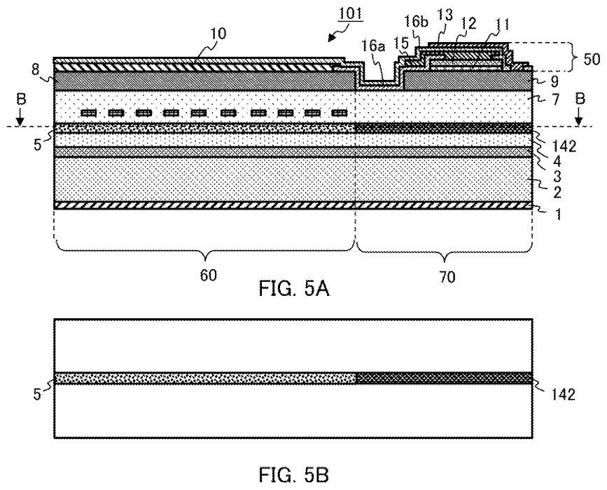

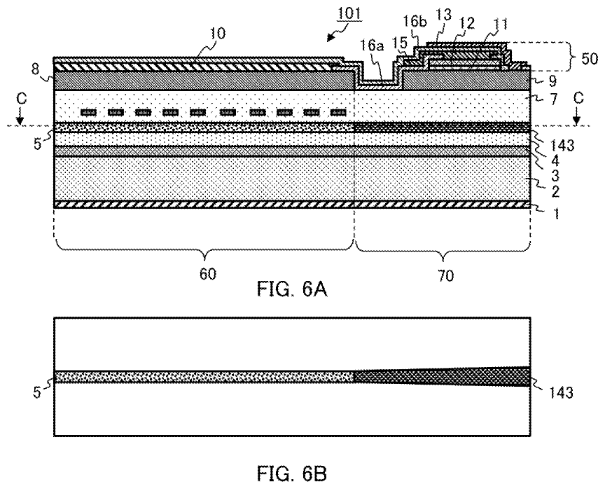

The optical waveguide 14 of the semiconductor optical integrated device 101 according to Embodiment 1 is provided so as to have a core layer whose thickness or width is constant in the propagation direction of the laser light; however, this is not limitative. For example, as shown in FIG. 4, such an optical waveguide 141 may instead be provided that has a core layer in a tapered shape that is tapered down in the propagation direction of the laser light. Note that the optical waveguide may be an optical waveguide 142 having a core layer extending to an end face of the device (see, FIG. 5), and may be an optical waveguide 14 having a window structure core layer not extending to the end face of the device (see, FIG. 1). FIG. 5(a) is a sectional view showing another configuration about a semi-conductor optical integrated device according to Embodiment 1, and FIG. 5(b) is a sectional view at a B-B arrow position in FIG. 5(a). Further, as shown in FIG. 6, the optical waveguide may instead be a flare-shaped optical waveguide 143 having a core layer that becomes wider in the propagation direction of the laser light. FIG. 6(a) is a sectional view showing another configuration about a semiconductor optical integrated device according to Embodiment 1, and FIG. 6(b) is a sectional view at a C-C arrow position in FIG. 6(a).

The semiconductor optical integrated device 101 of this application is characterized in that, with respect to the monitor PD section 50 as a mesa-type light receiving part that includes the contact layer 9 and has a p-n junction in its upper portion, the regions of the anode electrode and the cathode electrode each connected in the monitor PD section 50, or the regions of the electrode in the monitor PD section 50 and the LD anode electrode, are partially opposed to each other through the insulating film 16b.

In FIG. 1 to FIG. 3, the regions of the PD anode electrode 13 and the PD cathode electrode 15 in the monitor PD 50 are partially opposed to each other across the insulating film 16b, to thereby establish a capacitor structure. Assuming that the opposite area is S, the relative dielectric constant is ε, the dielectric constant of vacuum is ε₀ and the thickness of the insulating film is d, its capacitance C is represented by:

C=εε₀S/d

For example, the capacitance C is given as 50.5 pF in the case where the insulating film is of SiO₂, the insulating film thickness d is 0.2 μm, the relative dielectric constant ε is 3.8 and the area S is 1.5E-7 m².

According to JEDEC (JEDEC Solid State Technology Association) JESD22-A114 Standard, the capacitance of a human body is assumed to be about 100 pF. Thus, when a part of electric charges from the human body, after traveling along the human hand, flows into the above capacitance through the PD cathode electrode or the PD anode electrode of the monitor PD, to be stored partially therein, the voltage applied to the monitor PD is given as V=100 pF/(C+100 pF)V₀ (where V₀ denotes an externally-applied surge voltage), so that, according to the above case, the surge voltage applied to the monitor PD is reduced by about 33%.

In this manner, because a capacitance is created between such double-layered electrodes that are opposed to each other through the insulating film, a part of electric charges from the human body will be stored partially in the capacitance and thus the voltage applied to the monitor PD will be reduced, so that the surge breakdown voltage of the monitor PD section is increased. Further, because the surge breakdown voltage of the monitor PD section is increased, it is possible to ease the management of the ESD (Electrostatic Discharge) level in a manufacturing site, etc. related to this product, and this contributes to the improvement of the productivity.

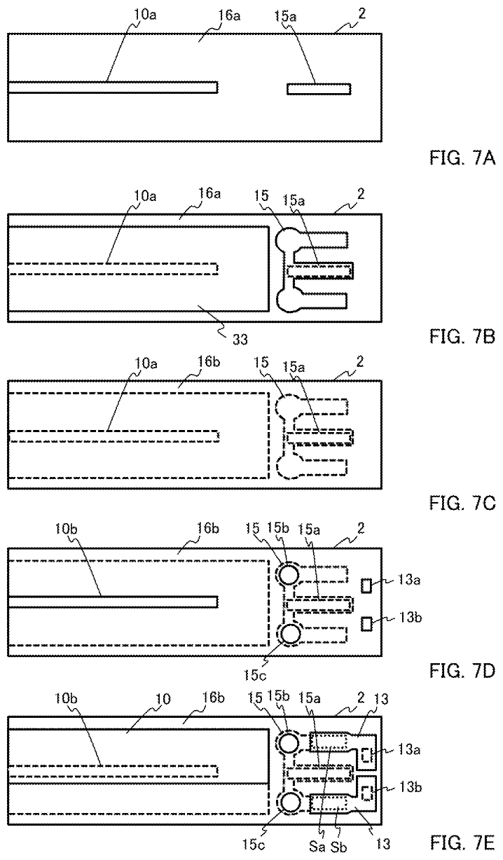

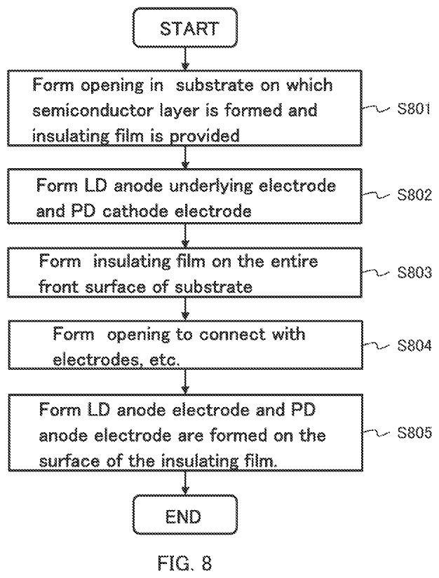

Next, a manufacturing method of the double-layered electrodes of the semiconductor optical integrated device 101 according to Embodiment 1 will be described on the basis of FIG. 7 and FIG. 8. FIG. 7 is a set of top views for illustrating the manufacturing method of the double-layered electrodes of the semi-conductor optical integrated device 101 according to Embodiment 1. FIG. 8 is a flowchart for illustrating steps in the manufacturing method of the double-layered electrodes of the semiconductor optical integrated device 101 according to Embodiment 1.

First of all, after the front surface of the n-type indium phosphide substrate 2 is subjected to semiconductor crystal growth and mesa etching is applied for a region for forming the monitor PD section and then the insulating film 16a made of SiO₂ is formed over the entire front surface by sputtering or the like, as shown in FIG. 7(a), an opening 10a serving as a region for making contact with the p-type InGaAs contact layer 8 of the semiconductor laser section 60 and an opening 15a serving as a region for making contact with the n-InGaAs contact layer 12 of the monitor PD section 50, are created by dry etching or the like (Step S801).

Subsequently, as shown in FIG. 7(b), on the surface of the insulating film 16a, the LD anode underlying electrode 33 of the semiconductor laser section 60 and the PD cathode electrode 15 of the monitor PD section are formed so as to fill the respective openings 10a, 15a (Step S802).

Then, as shown in FIG. 7(c), over the entire front surface of the n-type indium phosphide substrate 2 on which the PD cathode electrode 15 of the monitor PD section 50 as well as the LD anode underlying electrode 33 are formed, the insulating film 16b made of SiO₂ is formed by sputtering or the like (Step S803).

Subsequently, as shown in FIG. 7(d), an opening 10b serving as a region for making contact with the LD anode underlying electrode 33, openings 15b, 15c serving as regions for making contact with the PD cathode electrode 15, and openings 13a, 13b serving as regions for making contact with the p-type InGaAs contact layer 9, are created by dry etching or the like (Step S804).

Lastly, as shown in FIG. 7(e), on the surface of the insulating film 16b, the LD anode electrode 10 and the PD anode electrodes 13 are formed (Step S805). At this time, the PD anode electrodes 13 form regions Sa, Sb where they are opposed to the PD cathode electrode 15 through the insulating film 16b.

It is noted that although the insulating films 16a, 16b are made of SiO₂ in Embodiment 1, they may be insulating films made of a material of SiN, Si or the like, and an effect similar to the above will be presented thereby. Further, as the material and the structure of the active layer 5 in the semiconductor laser section, an InGaAsP multi-layer quantum well, an InGaAlAs multi-layer quantum well, a GaInAlN multi-layer quantum well or the like may be employed.

Further, as the material for the LD anode electrode 10 in the semiconductor laser section 60, and the PD cathode electrode 13 and the PD anode electrode 15 in the monitor PD section 50, Ti/Pt/Au, Ti/Au or Cr/Au may be used. Further, the structure of the current blocking layers 21, 22 may instead be such a structure in which p-InP, n-InP and p-InP are stacked in this order.

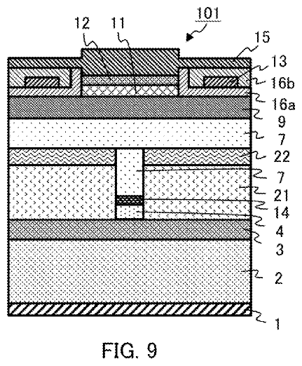

FIG. 9 is a sectional view showing another configuration about a semiconductor optical integrated device 101 according to Embodiment 1. As shown in FIG. 9, in the semiconductor optical integrated device 101, PD anode electrodes 13 of the monitor PD 50 are provided under a PD cathode electrode 15 of the monitor PD. Accordingly, even in the other configuration of the semiconductor optical integrated device 101, the regions of the PD anode electrode 13 and the PD cathode electrode 15 in the monitor PD 50 are partially opposed to each other through the insulating film 16b, to establish a capacitor structure.

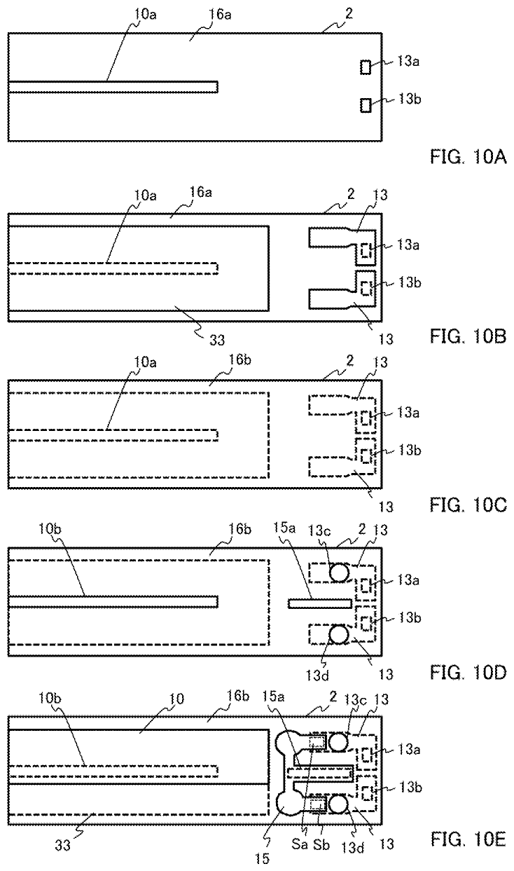

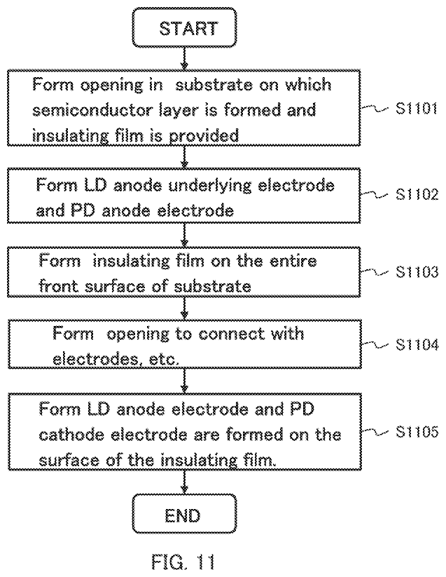

FIG. 10 is a set of top views for illustrating another manufacturing method of such double-layered electrodes of a semiconductor optical integrated device 101 according to Embodiment 1. FIG. 11 is a flowchart for illustrating steps in the other manufacturing method of the double-layered electrodes of the semiconductor optical integrated device 101 according to Embodiment 1. In the following, the other manufacturing method of the double-layered electrodes of the semiconductor optical integrated device 101 according to Embodiment 1 will be described on the basis of FIG. 10 and FIG. 11.

First of all, after the front surface of the n-type Indium phosphide substrate 2 is subjected to semiconductor crystal growth and mesa etching is applied for a region for forming the monitor PD section and then the insulating film 16a made of SiO₂ is formed over the entire front surface by sputtering or the like, as shown in FIG. 10(a), an opening 10a serving as a region for making contact with the p-type InGaAs contact layer 8 of the semiconductor laser section 60, and openings 13a, 13b serving as regions for making contact with the p-type InGaAs contact layer 9 of the monitor PD section 50, are created by dry etching or the like (Step S1101).

Subsequently, as shown in FIG. 10(b), on the surface of the insulating film 16a, the LD anode underlying electrode 33 of the semiconductor laser section 60 and the PD anode electrodes 13 of the monitor PD section 50 are formed so as to fill the respective opening 10a, 13a, 13b (Step S1102).

Then, as shown in FIG. 10(c), over the entire front surface of the n-type indium phosphide substrate 2 on which the PD anode electrodes 13 of the monitor PD section as well as the LD anode underlying electrode 33 are formed, the insulating film 16b made of SiO₂ is formed by sputtering or the like (Step S1103).

Subsequently, as shown in FIG. 10(d), an opening 10b serving as a region for making contact with the LD anode underlying electrode 33, an openings 15a serving as a region for making contact with the n-InGaAs contact layer 12, and openings 13c, 13d serving as regions for making contact with the PD anode electrodes 13, are created by dry etching or the like (Step S1104).

Lastly, as shown in FIG. 10(e), on the surface of the insulating film 16b, the LD anode electrode 10 and the PD cathode electrode 15 are formed (Step S1105). At this time, the PD cathode electrode 15 forms regions Sa, Sb where it is opposed to the PD anode electrodes 13 through the insulating film 16b.

As described above, the semiconductor optical integrated device 101 according to Embodiment 1 is configured to include: the semiconductor laser section formed on a surface of the semiconductor substrate 1; the spot-size converter section 70 in which the optical waveguide 14 having a core layer for propagating the laser light emitted from the semiconductor laser section 60 is provided; and the monitor PD section 50 which is provided on the spot-size converter section 70 laterally with respect to the propagation direction of the laser light; wherein the regions of the PD anode electrode 13 and the PD cathode electrode 15 in the monitor PD section 50 are partially opposed to each other through the insulating film 16b. Accordingly, a capacitance is created between such double-layered electrodes that are opposed to each other through the insulating film, so that a part of electric charges from a human body will be stored partially in the capacitance. Thus, the voltage applied to the monitor PD will be reduced, so that the surge breakdown voltage of the monitor PD section is increased. Further, because the surge breakdown voltage of the monitor PD section is increased, it is possible to ease the management of the ESD level in a manufacturing site, etc. related to this product, and this contributes to the improvement of the productivity.

Further, an effect similar to the above can be achieved not only in the case where the optical waveguide 14 is provided so as to have a core layer whose thickness or width is constant in the propagation direction of the laser light, but also in the cases where it is provided as a flare-shaped optical waveguide having a core layer that becomes wider in the propagation direction of the laser light, and where its core layer extends to an end face of the device, or does not extend to the end face and thus has a window structure. This is because the ESD immunity of the monitor PD does not depend on the structure of the optical waveguide and the difference in the monitoring current amount due to the difference in the structure.

### Embodiment 2

In Embodiment 1, a case has been described where the regions of the PD anode electrode 13 and the PD cathode electrode 15 in the monitor PD section 50 are partially opposed to each other through the insulating film 16b, whereas, in Embodiment 2, a case will be described where a PD cathode electrode in the monitor PD section and a front-surface side electrode in the semiconductor laser section are also opposed to each other.

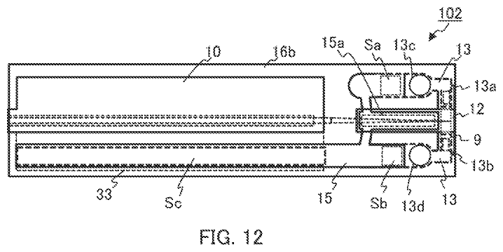

FIG. 12 is a top view showing a configuration of a semiconductor optical integrated device 102 according to Embodiment 2. As shown in FIG. 12, a PD cathode electrode 15 in the monitor PD section 50 and an LD anode underlying electrode 33 on the front-surface side in the semiconductor laser section 60, form a region Sc where their regions are partially opposed to each other through the insulating film 16b. The other configuration of the semiconductor optical integrated device 102 according to Embodiment 2 and the manufacturing method thereof are similar to those of the semiconductor optical integrated device 101 of Embodiment 1 (FIG. 7, FIG. 8), so that the same reference numerals are given to the corresponding parts and description thereof are omitted here.

Since the PD cathode electrode 15 and the LD anode underlying electrode 33 in the semiconductor laser section 60 are opposed in this manner and thus a capacitance is created therebetween, the surge voltage is reduced and not only that, the capacitance becomes larger than that in Embodiment 1. This contributes more to the improvement of the surge breakdown voltage.

As described above, according to the semiconductor optical integrated device 102 according to Embodiment 2, the regions of the PD anode electrode and the PD cathode electrode 15 in the monitor PD section 50 are partially opposed to each other through the insulating film 16b and not only that, the regions of the PD cathode electrode 15 and the LD anode underlying electrode 33 as the front-surface side electrode in the semiconductor laser section 60 are partially opposed to each other through the insulating film 16b. This makes the surge voltage reduced and not only that, this contributes more to the improvement of the surge breakdown voltage than in Embodiment 1.

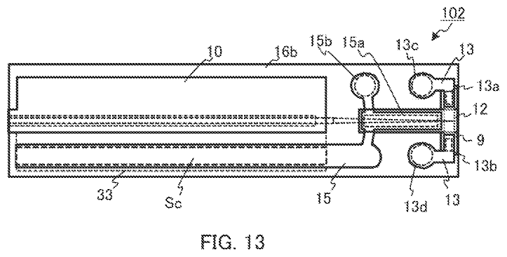

It is noted that, in Embodiment 2, the regions of the PD anode electrode 13 and the PD cathode electrode 15 in the monitor PD section 50 as well as the regions of the PD cathode electrode 15 and the LD anode underlying electrode 33 on the front-surface side in the semiconductor laser section 60, are partially opposed to each other through the insulating film 16b; however, this is not limitative. For example, only the regions of the PD cathode electrode 15 and the LD anode underlying electrode 33 on the front-surface side in the semiconductor laser section 60 may be partially opposed to each other through the insulating layer 16b (see, FIG. 13). Even if this is the case, it is possible to achieve an effect similar to that in Embodiment 1.

### Embodiment 3

In Embodiment 2, a case has been described where the PD cathode electrode 15 in the monitor PD section 50 and the front-surface side electrode in the semi-conductor laser section 60 are opposed to each other, whereas, in Embodiment 3, a case will be described where a PD anode electrode in the monitor PD section and a front-surface side electrode in the semiconductor laser section are opposed to each other.

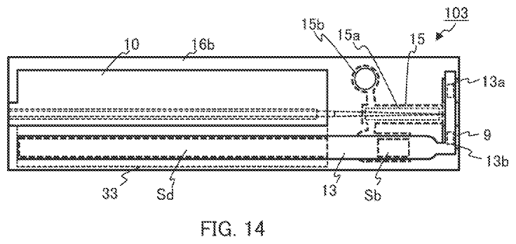

FIG. 14 is a top view showing a configuration of a semiconductor optical integrated device 103 according to Embodiment 3. As shown in FIG. 14, a PD anode electrode 13 in the monitor PD 50 and an LD anode underlying electrode 33 on the front-surface side in the semiconductor laser section 60, form a region Sd where their regions are partially opposed to each other through the insulating film 16b. The other configuration of the semiconductor optical integrated device 103 according to Embodiment 3 and the manufacturing method thereof are similar to those of the semiconductor optical integrated device 101 of Embodiment 1 (FIG. 2 to FIG. 4), so that the same reference numerals are given to the corresponding parts and description thereof are omitted here.

Since the PD anode electrode 13 and the LD anode underlying electrode 33 in the semiconductor laser section 60 are opposed in this manner and thus a capacitance is created therebetween, the surge voltage is reduced and not only that, the capacitance becomes larger than that in Embodiment 1. This contributes more to the improvement of the surge breakdown voltage.

As described above, according to the semiconductor optical integrated device 103 according to Embodiment 3, the regions of the PD anode electrode 13 and the PD cathode electrode 15 in the monitor PD section 50 are partially opposed to each other through the insulating film 16b and not only that, the regions of the PD anode electrode 13 and the LD anode underlying electrode 33 as the front-surface side electrode in the semiconductor laser section 60 are partially opposed to each other through the insulating layer 16b. This makes the surge voltage reduced and not only that, this contributes more to the improvement of the surge breakdown voltage than in Embodiment 1.

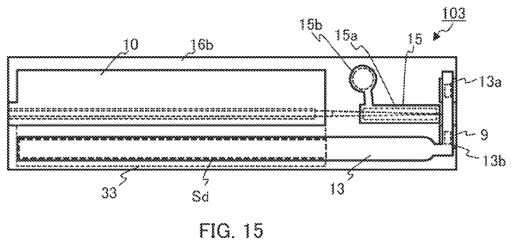

It is noted that, in Embodiment 2, the regions of the PD anode electrode 13 and the PD cathode electrode 15 in the monitor PD section 50 as well as the regions of the PD anode electrode 13 and the LD anode underlying electrode 33 on the front-surface side in the semiconductor laser section 60, are partially opposed to each other through the insulating film 16b; however, this is not limitative. For example, only the regions of the PD anode electrode 13 and the LD anode underlying electrode 33 on the front-surface side in the semiconductor laser section 60 may be partially opposed to each other through the insulating film 16b (see, FIG. 15). Even if this is the case, it is possible to achieve an effect similar to that in Embodiment 1.

In this application, a variety of exemplary embodiments and examples are described; however, every characteristic, configuration or function that is described in one or more embodiments, is not limited to being applied to a specific embodiment, and may be applied singularly or in any of various combinations thereof to another embodiment. Accordingly, an infinite number of modified examples that are not exemplified here are supposed within the technical scope disclosed in the present description. For example, such cases shall be included where at least one configuration element is modified; where at least one configuration element is added or omitted; and furthermore, where at least one configuration element is extracted and combined with a configuration element of another embodiment.

### DESCRIPTION OF REFERENCE NUMERALS AND SIGNS

2: n-type indium phosphide substrate, 13: PD anode electrode, 14: optical waveguide, 15: PD cathode electrode, 16b: insulating film, 33: LD anode underlying electrode, 50: monitor PD section, 60: semiconductor laser section, 70: spot-size converter section (light propagation section), 101, 102, 103: semiconductor optical integrated device.

1.-7. (canceled)

8. A semiconductor optical integrated device, comprising:
a semiconductor laser section formed on a surface of a semiconductor substrate;
a light propagation section in which an optical waveguide having a core layer for propagating laser light emitted from the semiconductor laser section is provided; and
a monitor photodiode section which is provided on the light propagation section laterally with respect to a propagation direction of the laser light;
wherein, a part of a region of one of electrodes in the monitor photodiode section is opposed, only across an insulating film, to a part of a region of another one of the electrodes in the monitor photodiode section and/or a part of a region of a front-surface side electrode in the semiconductor laser section.

9. The semiconductor optical integrated device of claim 8, wherein said one of the electrodes is an anode electrode and said another one of the electrodes is a cathode electrode.

10. The semiconductor optical integrated device of claim 8, wherein said one of the electrodes is a cathode electrode and said another one of the electrodes is an anode electrode.

11. The semiconductor optical integrated device of claim 8, wherein the optical waveguide in the light propagation section has the core layer which is provided in a tapered shape that is tapered down in the propagation direction of the laser light.

12. The semiconductor optical integrated device of claim 9, wherein the optical waveguide in the light propagation section has the core layer which is provided in a tapered shape that is tapered down in the propagation direction of the laser light.

13. The semiconductor optical integrated device of claim 10, wherein the optical waveguide in the light propagation section has the core layer which is provided in a tapered shape that is tapered down in the propagation direction of the laser light.

14. A manufacturing method of a semiconductor optical integrated device, comprising,
a step of forming, using a light propagation section in which an optical waveguide portion having a core layer for propagating laser light emitted from a semiconductor laser section formed on a surface of a semiconductor substrate is provided, a monitor photo-diode section on the light propagation section to be provided laterally with respect to a propagation direction of the laser light,
wherein, in said step of forming the monitor photodiode section, the monitor photodiode section is formed so that a part of a region of one of electrodes in the monitor photodiode section is opposed, only across an insulating film, to a part of a region of another one of the electrodes in the monitor photodiode section and/or a part of a region of a front-surface side electrode in the semiconductor laser section.

15. The manufacturing method of a semiconductor optical integrated device of claim 14, wherein said one of the electrodes is an anode electrode and said another one of the electrodes is a cathode electrode.

16. The manufacturing method of a semiconductor optical integrated device of claim 14, wherein said one of the electrodes is a cathode electrode and said another one of the electrodes is an anode electrode.
